(19) United States
(12) Patent Application Publication
(10) Pub. No.: US 2026/0173684 A1
(43) Pub. Date: Jun. 18, 2026

(54) DISPLAY DEVICE

(71) Applicant: LG Display Co., Ltd., Seoul (KR)

(72) Inventor: YeounJei JUNG, Daegu (KR)

(73) Assignee: LG Display Co., Ltd., Seoul (KR)

(21) Appl. No.: 19/331,772

(22) Filed: Sep. 17, 2025

(30) Foreign Application Priority Data
Dec. 18, 2024 (KR) 10-2024-0190481

(51) Int. Cl. H10K 59/131; H10K 59/80

(52) U.S. Cl. CPC H10K 59/131; H10K 59/873

(57) ABSTRACT

A display device according to one or more examples includes: light-emitting elements respectively disposed in subpixels on a substrate, each including an anode; a light-emitting layer, and a cathode; a bank disposed in a display area and a non-display area and covering an end of the anode; a dam disposed in the non-display area on the substrate and surrounding the display area; and a power line partially overlapping the dam in the non-display area, disposed on a same layer as the anode, and made of a same material as the anode, in which the power line includes: a first portion overlapping the dam; and a second portion extending from the first portion toward the display area, and in which the bank includes: first opening portions disposed along the dam; and a second opening portion extending from a first opening portion and disposed along a side surface of the second portion.

### CROSS-REFERENCE TO RELATED APPLICATIONS

This application claims the benefit of and priority to Korean Patent Application No. 10-2024-0190481 filed on Dec. 18, 2024, in the Korean Intellectual Property Office, the entire contents of which are incorporated herein by reference for all purposes.

### BACKGROUND

### 1. Technical Field

The present disclosure relates to a display device, and more particularly, for example, without limitation, to a display device capable of minimizing moisture permeation into a display area while minimizing damage to a power line disposed in a non-display area.

### 2. Description of Related Art

Display devices, which visually display electrical information signals, are being rapidly developed in accordance with the entry into the information era. Various studies are being continuously conducted to develop a variety of display devices which are thin and lightweight, consume low power, and have improved performance.

As the representative display devices, there may be a liquid crystal display device (LCD), a field emission display device (FED), an electrowetting display device (EWD), an organic light-emitting display device (OLED), and the like.

An electroluminescent display device, as the representative organic light-emitting display device, refers to a display device that autonomously emits light. Unlike a liquid crystal display device, the electroluminescent display device does not require a separate light source and thus may be manufactured as a lightweight, thin display device. In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios (CRs).

The description of related art should not be considered prior art merely because it is mentioned in or associated with this section. The description of related art includes information that describes one or more aspects of the subject technology, and the description in this section does not limit the scope of the invention.

### SUMMARY

An aspect to be achieved by the present disclosure is to provide a display device capable of minimizing damage to a power line disposed in a non-display area during a manufacturing process.

Another aspect to be achieved by the present disclosure is to provide a display device capable of inhibiting moisture from permeating into a display area.

Aspects of the present disclosure are not limited to the above-mentioned aspects, and other aspects, which are not mentioned above, can be clearly understood by those skilled in the art from the following descriptions.

A display device according to one embodiment of the present disclosure includes: a substrate; a display area in which a plurality of subpixels are disposed, and a non-display area outside the display area; a plurality of light-emitting elements respectively disposed in the plurality of subpixels on the substrate, each light-emitting element including an anode, a light-emitting layer, and a cathode; a bank disposed in the display area and the non-display area and covering an end of the anode; a dam disposed in the non-display area on the substrate and configured to surround the display area; and a power line configured to partially overlap the dam in the non-display area, disposed on a same layer as the anode, and made of a same material as the anode, in which the power line includes: a first portion that is a portion overlapping the dam; and a second portion that is a portion extending from the first portion toward the display area, and in which the bank includes: a plurality of first opening portions disposed along the dam; and a second opening portion extending from a first opening portion and disposed along a side surface of the second portion. The plurality of first opening portions may include the first opening portion.

A display device according to another embodiment of the present disclosure includes: a substrate; a display area and a non-display area; a plurality of light-emitting elements disposed in the display area on the substrate, each light-emitting element including an anode, a light-emitting layer, and a cathode; a bank disposed on the anode and covering an end of the anode; and a power line disposed in the non-display area, disposed on a same layer as the anode, made of a same material as the anode, and electrically connected to the cathode, in which the power line includes: a first portion disposed in the non-display area and disposed to surround at least a part of the display area; and a second portion that is a portion protruding from the first portion toward the display area, and in which the bank includes: a plurality of first opening portions disposed to surround at least a part of the display area and configured to at least partially overlap the first portion; and a second opening portion disposed to extend from a first opening portion along a side surface of the second portion. The plurality of first opening portions may include the first opening portion.

Other detailed matters of the example embodiments are included in the detailed description and the drawings.

In one or more aspects of the present disclosure, it is possible to improve reliability of the display device by minimizing damage to the power line during the manufacturing process.

In one or more aspects of the present disclosure, it is possible to improve reliability and display quality of the display device by minimizing moisture permeation into the display area.

In one or more aspects of the present disclosure, it is possible to improve a production yield by minimizing damage to the power line during the manufacturing process and optimize the process by reducing production energy.

The effects according to the present disclosure are not limited to the contents exemplified above, and more various effects are included in one or more aspects of the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a top plan view of a display device according to an embodiment of the present disclosure;

FIG. 2 is a cross-sectional view taken along line A-A′ in FIG. 1;

FIGS. 3A to 3C are enlarged top plan views of area B in FIG. 1;

FIG. 4 is a cross-sectional view taken along line C-C′ in FIG. 3A;

FIG. 5 is an enlarged top plan view of a display device according to another embodiment of the present disclosure;

FIGS. 6A and 6B are enlarged top plan views of a display device according to still another embodiment of the present disclosure;

FIG. 7 is an enlarged top plan view of a display device according to yet another embodiment of the present disclosure;

FIG. 8 is an enlarged top plan view of a display device according to still yet another embodiment of the present disclosure;

FIG. 9 is an enlarged top plan view of a display device according to a further embodiment of the present disclosure; and

FIG. 10 is an enlarged top plan view of a display device according to another further embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “comprising,” ‘including’, ‘having’, ‘consist of’ used herein are generally intended to allow other components to be added unless the terms are used with the term ‘only’. Any references to singular may include plural unless expressly stated otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

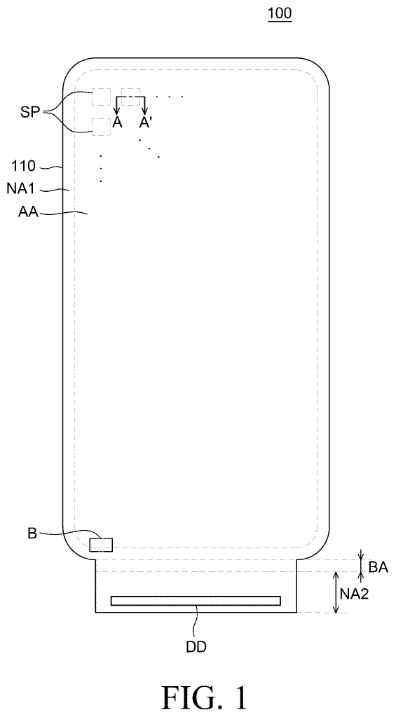

FIG. 1 is a schematic top plan view of a display device according to an embodiment of the present disclosure.

With reference to FIG. 1, a substrate 110 includes a display area AA and a non-display area.

The substrate 110 is a base member for supporting various types of components of a display device 100 and may be made of an insulating material. For example, the substrate 110 may be made of a plastic material such as glass or polyimide.

The display area AA is an area in which images are displayed. The plurality of subpixels SP and a driver for operating the plurality of subpixels SP are disposed in the display area AA. The plurality of subpixels SP is minimum units that constitute the display area AA. The n subpixels SP may constitute a single pixel. For example, the subpixels SP may include a red subpixel, a green subpixel, and a blue subpixel or include a white subpixel, a red subpixel, a green subpixel, and a blue subpixel. The subpixel SP may have one or more different light-emitting areas depending on luminous properties.

For example, the driver may include various constituent elements such as a power line, a gate line, a data line, a transistor, and a storage capacitor for operating the plurality of subpixels SP. However, the present disclosure is not limited thereto.

With reference to FIG. 1, the substrate 110 may have variant corner areas. The display area AA may have a shape corresponding to the variant corner areas of the substrate 110. The corners of the substrate 110 and the corners of the display area AA may each have a rounded shape. However, the present disclosure is not limited thereto. The substrate 110 and the display area AA may have various shapes suitable for a design of an electronic apparatus equipped with the display device 100.

The non-display area is an area in which no image is displayed. Various lines, various circuits, and the like for operating the display elements in the display area AA are disposed in the non-display area. For example, a data driver DD, a gate driver, a link line, a pad part, and the like may be disposed in the non-display area.

The non-display area may be an area extending from the display area AA. However, the present disclosure is not limited thereto. The non-display area may be an area that surrounds the display area AA.

The non-display area includes a first non-display area NA1, a bending area BA, and a second non-display area NA2. The first non-display area NA1 is an area extending from the display area AA. The bending area BA is an area extending from the first non-display area NA1. The bending area BA may be bent. The second non-display area NA2 is an area extending from the bending area BA.

The data driver DD may be disposed in the second non-display area NA2. Although not illustrated, the pad part having pads connected to various types of signal lines or a PCB may be further disposed in the second non-display area NA2. For example, a power supply pad, a data pad, a gate pad, and the like may be disposed on the pad part.

The data driver DD may be mounted on or connected to a separate PCB and connected to a display panel through the pad part. Alternatively, the data driver DD may be mounted or connected, in the form of a chip-on-panel (COP) between the pad part and the display area AA. The data driver DD includes at least one source drive integrated circuit (IC). The at least one source drive IC is supplied with digital video data and a source timing control signal from a timing controller. The at least one source drive IC generates a data voltage by converting digital video data into a gamma voltage in response to the source timing control signal and supplies the data voltage through the data line in the display area AA.

The bending area BA may be an area in which the substrate 110 is bent. For example, the substrate 110 may be maintained in a flat state without being bent in an area excluding the bending area BA, and the substrate 110 may be configured to be bent in the bending area BA. Therefore, the display device 100 may be bent so that two non-bent areas of the substrate 110, except for the bending area BA of the substrate 110, face each other.

The second non-display area NA2 is an area between the bending area BA and the display area AA. The link lines such as a power link line and a data link line may be disposed in the second non-display area NA2. That is, the second non-display area NA2 serves to transmit a signal, which is outputted from the driver, to the display area AA. In the case in which the substrate 110 includes the variant corner areas, the second non-display area NA2 may have a shape corresponding to the shape of the substrate 110 and the shape of the display area AA.

Although not illustrated, the gate drivers may be disposed at two opposite sides of the display area AA in the second non-display area NA2 of the non-display area. The gate driver may be implemented by a gate-in-panel (GIP) method. However, the present disclosure is not limited thereto.

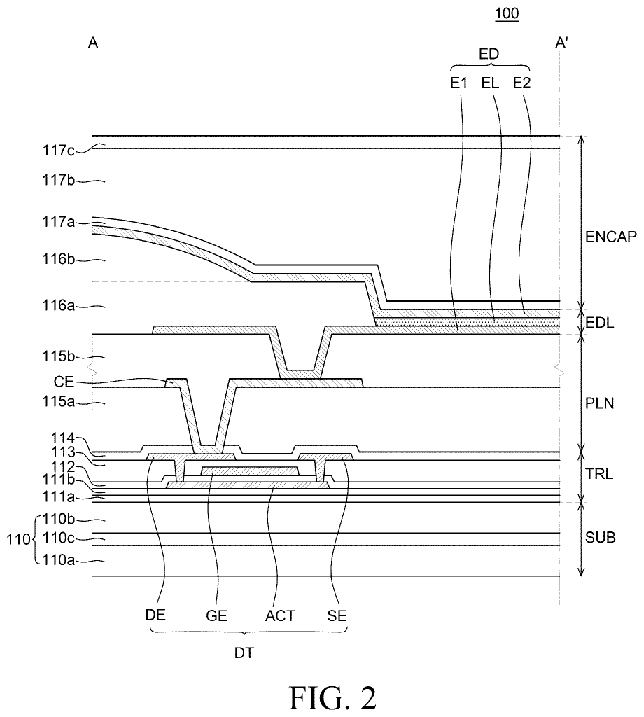

Hereinafter, cross-sectional structures of the plurality of subpixels SP disposed in the display area AA of the display device 100 will be described in more detail with reference to FIG. 2.

FIG. 2 is a cross-sectional view taken along line A-A′ in FIG. 1. FIG. 2 is a cross-sectional view of one subpixel SP disposed in the display area AA of the display device 100 according to the embodiment of the present disclosure.

With reference to FIG. 2, in the subpixel SP disposed in the display area AA, a transistor layer TRL may be disposed above a substrate layer SUB, and a planarization layer PLN may be disposed above the transistor layer TRL. In addition, a light-emitting element layer EDL may be disposed above the planarization layer PLN, and an encapsulation layer ENCAP may be disposed above the light-emitting element layer EDL.

The substrate layer SUB may be configured to support various constituent elements included in the display device 100 and include the substrate 110 having a plurality of layers. For example, the substrate 110 may be made of an insulating material. The substrate 110 may include a first substrate 110a, a second substrate 110b, and an insulation layer 110c. The insulation layer 110c may be disposed between the first substrate 110a and the second substrate 110b. As described above, the substrate 110 is configured by the first substrate 110a, the second substrate 110b, and the insulation layer 110c, which may suppress the moisture permeation. For example, the first substrate 110a and the second substrate 110b may each be a substrate made of polyimide (PI).

Various types of patterns GE, DE, SE, and ACT for forming a transistor such as a driving transistor DT and various types of insulation layers 111a, 111b, 112, 113, and 114 may be disposed on the transistor layer TRL in the display area AA.

Hereinafter, a layered structure of the transistor layer TRL will be described in more detail.

A multi-buffer layer 111a may be disposed on the second substrate 110b, and an active buffer layer 111b may be disposed on the multi-buffer layer 111a. The multi-buffer layer 111a and the active buffer layer 111b may each be made of an inorganic insulating material and include at least any one of silicon nitride (SiNx) and silicon oxide (SiOx), for example.

Although not illustrated, a light-blocking layer, which serves as a light shield, may be disposed on the multi-buffer layer 111a.

An active layer ACT of the driving transistor DT may be disposed on the active buffer layer 111b.

For example, the active layer ACT may include low-temperature poly-silicon (LTPS). Because a polysilicon material has high mobility (100 cm²/Vs or more), low energy power consumption, and excellent reliability, the polysilicon material may be applied to gate drivers and/or multiplexers (MUX) for driving elements for operating thin-film transistors for display elements. In the display device 100 according to the embodiment of the present disclosure, the polysilicon material may be applied to the active layer of the driving transistor DT. However, the present disclosure is not limited thereto. For example, the polysilicon material may also be applied to an active layer of a switching thin-film transistor in accordance with the characteristics of the display device.

The active layer ACT may include a channel area in which a channel is formed when the driving transistor DT operates, and source and drain areas disposed at two opposite sides of the channel area. The source area refers to a portion of the active layer ACT connected to a source electrode SE to be described below, and the drain area refers to a portion of the active layer ACT connected to a drain electrode DE to be described below. The source area and the drain area may be configured by doping the active layer ACT with ions (impurities). The source area and the drain area may be formed by doping the polysilicon material with ions. The channel area may refer to a portion in which the polysilicon material remains without being subjected to the ion doping.

For example, the active layer ACT may be made of an oxide semiconductor. The oxide semiconductor material is a material having a larger band gap than a silicon material and has a low off-current because electrons cannot pass through the band gap in an OFF state. Therefore, the thin-film transistor including the active layer ACT made of the oxide semiconductor may be suitable for a switching thin-film transistor that maintains the short ON time and the long OFF time. However, the present disclosure is not limited thereto. The oxide semiconductor material may also be applied to the thin-film driving transistor DT in accordance with the properties of the display device 100. Further, because the oxide semiconductor material has a low off-current and may decrease a magnitude of an auxiliary capacity, the oxide semiconductor material is suitable for a high-resolution display element. For example, the active layer ACT may be made of a metal oxide. For example, the active layer ACT may be made of various metal oxides such as indium-gallium-zinc-oxide (IGZO), indium-zinc-oxide (IZO), indium-gallium-tin-oxide (IGTO), or indium-gallium-oxide (IGO).

A gate insulation layer 112 may be disposed on the active layer ACT. The gate insulation layer 112 may be made of an inorganic insulating material, e.g., made of silicon oxide (SiOx), silicon nitride (SiNx), or a multilayer thereof.

In addition, a gate electrode GE of the driving transistor DT may be disposed on the gate insulation layer 112. The gate electrode GE is disposed on the gate insulation layer 112 and overlaps the active layer ACT. The gate electrode GE may be made of various electrically conductive materials, for example, any one selected from a group consisting of magnesium (Mg), aluminum (Al), nickel (Ni), chromium (Cr), molybdenum (Mo), tungsten (W), gold (Au), titanium (Ti), neodymium (Nd), and copper (Cu) or an alloy thereof. However, the present disclosure is not limited thereto.

An interlayer insulation layer 113 may be disposed to cover the gate electrode GE. The interlayer insulation layer 113 may be made of an inorganic insulating material or an organic insulating material. For example, the interlayer insulation layer 113 may be made of silicon oxide (SiOx), silicon nitride (SiNx), or a multilayer thereof.

The source electrode SE and the drain electrode DE of the driving transistor DT may be disposed on the interlayer insulation layer 113.

The source electrode SE and the drain electrode DE may be respectively connected to one side and the other side of the active layer ACT through contact holes provided in the interlayer insulation layer 113 and the gate insulation layer 112. The source electrode SE and the drain electrode DE may each be made of various electrically conductive materials, for example, any one selected from a group consisting of magnesium (Mg), aluminum (Al), nickel (Ni), chromium (Cr), molybdenum (Mo), tungsten (W), gold (Au), titanium (Ti), neodymium (Nd), and copper (Cu) or an alloy thereof. However, the present disclosure is not limited thereto.

A portion of the active layer ACT, which overlaps the gate electrode GE, is a channel area. One of the source electrode SE and the drain electrode DE is connected to one side of the channel area of the active layer ACT, and the other of the source electrode SE and the drain electrode DE is connected to the other side of the channel area of the active layer ACT.

A passivation layer 114 may be disposed on the source electrode SE and the drain electrode DE. The passivation layer 114 may serve to protect the driving transistor DT and be configured as an inorganic layer, for example, silicon oxide (SiOx), silicon nitride (SiNx), or a multilayer thereof.

The planarization layer PLN may be positioned above the transistor layer TRL.

The planarization layer PLN may include a first planarization layer 115a and a second planarization layer 115b. The planarization layer PLN protects the driving transistor DT and planarizes an upper portion of the driving transistor DT.

The first planarization layer 115a may be disposed on the passivation layer 114.

A connection electrode CE may be disposed on the first planarization layer 115a.

The connection electrode CE may be connected to one of the source electrode SE and the drain electrode DE through a contact hole provided in the first planarization layer 115a.

The second planarization layer 115b may be disposed on the connection electrode CE.

The light-emitting element layer EDL may be positioned above the second planarization layer 115b.

Hereinafter, a layered structure of the light-emitting element layer EDL will be described in detail.

An anode E1 may be disposed on the second planarization layer 115b. In this case, the anode E1 may be electrically connected to the connection electrode CE through a contact hole provided in the second planarization layer 115b. The anode E1 may be made of a metallic material.

In case that the display device 100 is a top-emission type display device in which light emitted from a light-emitting element ED propagates toward an upper side of the substrate 110 on which the light-emitting element ED is disposed, the anode E1 may further include a transparent conductive layer and a reflective layer disposed below the transparent conductive layer. For example, the transparent conductive layer may be made of transparent conductive oxide such as ITO or IZO. For example, the reflective layer may be made of silver (Ag), aluminum (Al), gold (Au), molybdenum (Mo), tungsten (W), chromium (Cr), or an alloy thereof.

A bank 116a may be disposed to cover the anode E1. A portion of the bank 116a, which corresponds to the light-emitting area of the subpixel SP, may be opened. A part of the anode E1 may be exposed through the opened portion (hereinafter, referred to as an open area) of the bank 116a. In this case, the bank 116a may be made of an inorganic insulating material such as silicon nitride (SiNx) or silicon oxide (SiOx), or an organic insulating material such as benzocyclobutene-based resin, acrylic resin, or imide-based resin. However, the present disclosure is not limited thereto.

A spacer 116b may be further disposed on the bank 116a. The spacer 116b may suppress damage to the light-emitting element ED that may be caused when a fine metal mask (FMM), which is used to form a light-emitting layer EL of the light-emitting element ED, comes into contact directly with the bank 116a or a cathode E2. The spacer 116b may be made of the same material as the bank 116a and made of an insulating material different from the insulating material of the bank 116a. However, the present disclosure is not limited thereto. In addition, the spacer 116b and the bank 116a may be integrated. As the spacer 116b is disposed on the bank 116a, the cathode E2 and the light-emitting layer EL may be disposed to cover the spacer 116b and the bank 116a.

The light-emitting layer EL may be disposed in the open area of the bank 116a. Therefore, the light-emitting layer EL may be disposed on the anode E1 exposed through the open area of the bank 116a.

The cathode E2 may be disposed on the light-emitting layer EL.

The light-emitting element ED may be formed by the anode E1, the light-emitting layer EL, and the cathode E2. The light-emitting layer EL may include a plurality of organic layers.

The encapsulation layer ENCAP may be positioned above the light-emitting element layer EDL.

The encapsulation layer ENCAP may have a single-layer or multilayer structure. For example, the encapsulation layer ENCAP may include a first encapsulation layer 117a, a second encapsulation layer 117b, and a third encapsulation layer 117c.

In this case, the first encapsulation layer 117a and the third encapsulation layer 117c may each be configured as an inorganic layer, and the second encapsulation layer 117b may each be configured as an organic layer. Among the first encapsulation layer 117a, the second encapsulation layer 117b, and the third encapsulation layer 117c, the second encapsulation layer 117b may be thickest and serve as a planarization layer.

The first encapsulation layer 117a may be disposed on the cathode E2 and closest to the light-emitting element ED. For example, the first encapsulation layer 117a may be made of silicon nitride (SiNx), silicon oxide (SiOx), silicon oxynitride (SiON), aluminum oxide (Al₂O₃), or the like.

The second encapsulation layer 117b may have a smaller area than the first encapsulation layer 117a. In this case, the second encapsulation layer 117b may be formed to expose two opposite ends of the first encapsulation layer 117a. The second encapsulation layer 117b may serve as a buffer for mitigating stress between the layers. The second encapsulation layer 117b may serve to improve the planarization performance.

For example, the second encapsulation layer 117b may be made of an organic insulating material such as acrylic resin, epoxy resin, polyimide, polyethylene, or silicon oxycarbon (SiOC). For example, the second encapsulation layer 117b may also be formed in an inkjet manner. However, the present disclosure is not limited thereto.

The third encapsulation layer 117c may be formed above the substrate 110 having the second encapsulation layer 117b to cover a top surface and a side surface of each of the second encapsulation layer 117b and the first encapsulation layer 117a. In this case, the third encapsulation layer 117c may minimize or block the permeation of outside moisture or oxygen into the first encapsulation layer 117a and the second encapsulation layer 117b. For example, the third encapsulation layer 117c may be made of an inorganic insulating material such as silicon nitride (SiNx), silicon oxide (SiOx), silicon oxynitride (SiON), or aluminum oxide (Al₂O₃). For example, the first encapsulation layer 117a and the third encapsulation layer 117c may be formed by a chemical vapor deposition (CVD) process that allows deposition at a low temperature by obtaining high reaction energy from plasma.

Meanwhile, although not illustrated, a polarizing layer may be further disposed on the encapsulation layer ENCAP. The polarizing layer suppresses reflection of external light in the display area AA of the substrate 110. In case that the display device 100 is used outside, external natural light may be introduced and reflected by the reflective layer included in the anode E1 of the light-emitting element ED or reflected by an electrode made of metal and disposed on a lower portion of the light-emitting element ED. The light beams, which are reflected as described above, may inhibit an image on the display device 100 from being visually recognized. The polarizing layer may polarize, in a particular direction, the light introduced from the outside, thereby inhibiting the reflected light from being discharged again to the outside of the display device 100.

Although not illustrated, a cover glass may be bonded onto the polarizing layer by a bonding layer. The bonding layer may serve to bond the constituent elements of the display device 100. For example, the bonding layer may be formed by using a bonding agent for an optically transparent display such as a pressure-sensitive bonding agent, an optically transparent bonding agent (optical clear adhesive (OCR)), or an optically transparent resin (optical clear resin (OCR)). However, the present disclosure is not limited thereto.

The cover glass may protect the constituent elements of the display device 100 from external impact and suppress damage such as scratches.

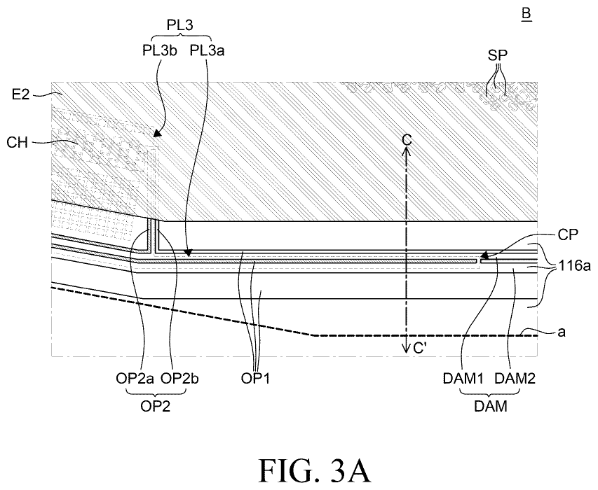

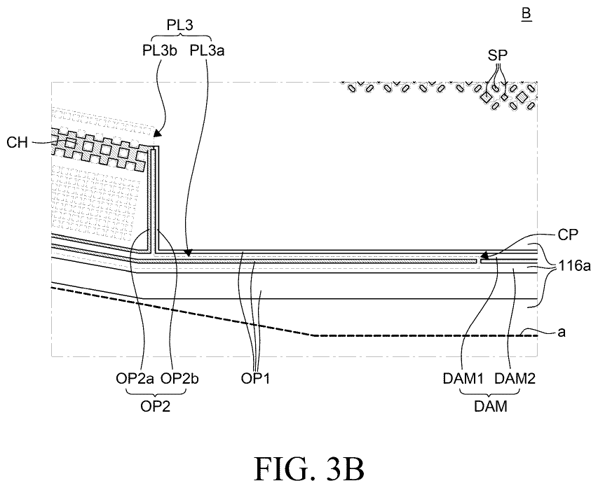

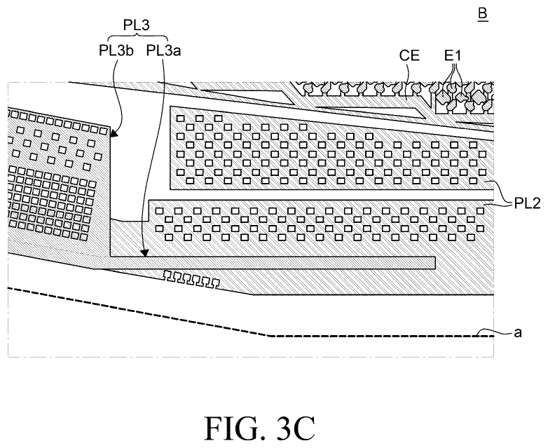

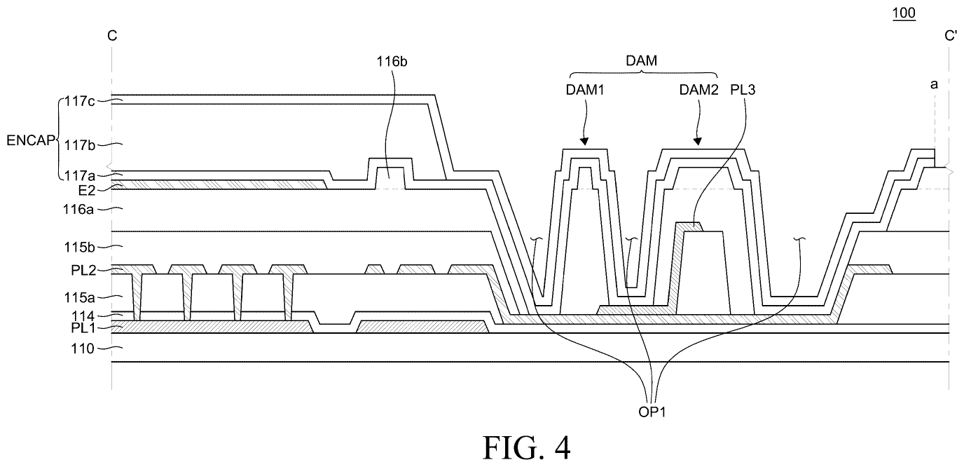

FIGS. 3A to 3C are enlarged top plan views of area B in FIG. 1. FIG. 4 is a cross-sectional view taken along line C-C′ in FIG. 3A. FIGS. 3A to 3C are top plan views for explaining an arrangement structure of a second power line PL2, a third power line PL3, the bank 116a, and the cathode E2 disposed in the first non-display area NA1. For convenience of description, FIG. 3A illustrates only the third power line PL3, the bank 116a, and the cathode E2 among various constituent elements of the display device 100, FIG. 3B illustrates only the third power line PL3 and the bank 116a among various constituent elements of the display device 100, and FIG. 3C illustrates only the second power line PL2 and the third power line PL3. FIG. 4 is a cross-sectional view of the first non-display area NA1 of the display device 100 according to the embodiment of the present disclosure. A repeated description of the constituent elements substantially identical to the constituent elements illustrated in FIG. 2 will be omitted from FIG. 4. The same reference numerals are used for the same components.

With reference to FIGS. 3A to 4, the substrate 110, a first power line PL1, the second power line PL2, the third power line PL3, the cathode E2, a plurality of dams DAM, the passivation layer 114, the first planarization layer 115a, the second planarization layer 115b, the bank 116a, the spacer 116b, and the encapsulation layer ENCAP are disposed in the first non-display area NA1 between the display area AA and the bending area BA. Meanwhile, FIG. 4 illustrates that another insulation layer or electrode is not disposed between the substrate 110 and the passivation layer 114. However, various insulation layers or electrodes disposed in the display area AA may be further disposed between the substrate 110 and the passivation layer 114. However, the present disclosure is not limited thereto.

With reference to FIGS. 3A, 3B, and 4, the plurality of dams DAM is disposed in the first non-display area NA1 and surround the display area AA.

The plurality of dams DAM may include a first dam DAM1 and a second dam DAM2. For example, the first dam DAM1 and the second dam DAM2 may be disposed to overlap the second power line PL2 and the third power line PL3 without overlapping the first planarization layer 115a.

For example, the plurality of dams DAM may block a flow of an organic layer, i.e., a flow of the second encapsulation layer 117b that constitutes the encapsulation layer ENCAP. Specifically, the plurality of dams DAM may be disposed in a closed curve shape in the first non-display area NA1 and surround the display area AA. Therefore, the second encapsulation layer 117b, which is made of an organic insulating material, may inhibit the second encapsulation layer 117b from flowing over in a direction of the first non-display area NA1 and entering the pad part when the second encapsulation layer 117b is applied onto the display area AA.

The plurality of dams DAM may have a predetermined height or higher to block a flow of the second encapsulation layer 117b. To this end, the plurality of dams DAM may be configured by one or more layers at least made of an organic material. However, the present disclosure is not limited thereto. For example, the plurality of dams DAM may be made of the same material as the second planarization layer 115b, the bank 116a, and the spacer 116b. However, the present disclosure is not limited thereto. In this case, it is possible to configure the plurality of dams DAM without a process of adding a mask and an increase in costs.

With reference to FIG. 4, the first power line PL1 may be disposed in the first non-display area NA1 and disposed on the substrate 110. The first power line PL1 may be disposed to be spaced apart from the plurality of dams DAM. For example, first power Vdd, i.e., a high-potential voltage may be supplied to the subpixel SP of the display device 100 through the first power line PL1. In this case, the first power line PL1 may be disposed on the same layer and made of the same material as the source electrode SE or the drain electrode DE disposed in the display area AA. However, the present disclosure is not limited thereto.

The passivation layer 114 and the first planarization layer 115a may be disposed to cover the first power line PL1. A plurality of contact holes for exposing the first power line PL1 may be formed in the passivation layer 114 and the first planarization layer 115a in the first non-display area NA1 between the display area AA and the plurality of dams DAM.

The second power line PL2 may be disposed on the first planarization layer 115a in the first non-display area NA1 between the display area AA and the plurality of dams DAM. With reference to FIG. 3C, the second power line PL2 may extend to the outside of the plurality of dams DAM from the first non-display area NA1 between the display area AA and the bending area BA and overlap the plurality of dams DAM. However, the present disclosure is not limited thereto. For example, the second power line PL2 may overlap the first dam DAM1 and the second dam DAM2 in the first non-display area NA1 between the display area AA and the bending area BA.

The second power line PL2 may be connected to the first power line PL1 through the plurality of contact holes disposed in the passivation layer 114 and the first planarization layer 115a in the first non-display area NA1 between the display area AA and the bending area BA. For example, second power VSS, i.e., a low-potential voltage may be supplied to the subpixel SP of the display device 100 through the second power line PL2. Therefore, the second power line PL2, the third power line PL3, and a second electrode E2 are electrically connected, such that the second power VSS may be applied to the subpixel SP of the display device 100. In this case, the second power line PL2 may be disposed on the same layer and made of the same material as the connection electrode CE disposed in the display area AA. However, the present disclosure is not limited thereto.

Meanwhile, with reference to FIGS. 3C and 4, the second power line PL2 may include a plurality of holes. For example, a gas, which is generated from the first planarization layer 115a or the second planarization layer 115b during the manufacturing process, may be easily discharged to the outside through the plurality of holes.

The second planarization layer 115b may be disposed on the second power line PL2 to cover the second power line PL2 in the first non-display area NA1 between the display area AA and the bending area BA.

The third power line PL3 may be disposed on at least a part of the second planarization layer 115b in the first non-display area NA1 between the display area AA and the bending area BA.

For example, the third power line PL3 may be disposed to overlap the first dam DAM1 and the second dam DAM2 in the first non-display area NA1 between the display area AA and the bending area BA. In this case, the third power line PL3 may be disposed on the same layer and made of the same material as the anode E1 disposed in the display area AA.

Meanwhile, with reference to FIGS. 3A to 3C, the third power line PL3 may include a first portion PL3a and a second portion PL3b.

The first portion PL3a of the third power line PL3 is a portion that overlaps the plurality of dams DAM. The first portion PL3a may be disposed to overlap at least a part of the display area AA. The first portion PL3a is disposed to overlap the first dam DAM1 and the second dam DAM2. The first portion PL3a may be disposed along at least a part of the first dam DAM1 and at least a part of the second dam DAM2 in a plan view and disposed in a shape that surrounds at least a part of the display area AA.

Meanwhile, with reference to FIGS. 3A, 3B, and 4, a side surface of the first portion PL3a, which is opposite to an inner side of the display device 100, is disposed to overlap the first dam DAM1, and a side surface of the first portion PL3a, which is opposite to an outer side of the display device 100, is disposed to overlap the second dam DAM2. Further, with reference to FIGS. 3A and 3B, a side surface of the first portion PL3a, which does not overlap the first dam DAM1 and the second dam DAM2, may overlap a connection portion CP that is a portion where the banks 116a respectively included in the first dam DAM1 and the second dam DAM2 extend and are connected to each other. Therefore, all the side surfaces of the first portion PL3a may be disposed to be covered at least by the bank 116a.

The second portion PL3b of the third power line PL3 is a portion extending from the first portion PL3a toward the display area AA. For example, as illustrated in FIG. 3C, the second portion PL3b may protrude from the first portion PL3a and have a polygonal shape in a plan view. However, the present disclosure is not limited thereto.

With reference to FIGS. 3A to 3C, the second portion PL3b may include a plurality of holes. For example, a gas, which is generated from the second planarization layer 115b or the bank 116a during the manufacturing process, may be easily discharged to the outside through the plurality of holes.

With reference to FIGS. 3A and 3B, the second portion PL3b of the third power line PL3 may be a portion that is in contact with the cathode E2 and electrically connected to the cathode E2. For example, a contact hole CH for exposing the third power line PL3 may be formed in the bank 116a that overlaps the second portion PL3b. Therefore, the third power line PL3 may be electrically connected to the cathode E2 through the contact hole CH formed in the bank 116a and supply the second power VSS, which is a low potential voltage, to the cathode E2.

The bank 116a may be disposed on at least a part of the second planarization layer 115b and at least a part of the third power line PL3 in the first non-display area NA1 between the display area AA and the bending area BA.

With reference to FIGS. 3A to 4, the bank 116a disposed in the first non-display area NA1 between the display area AA and the bending area BA includes a plurality of first opening portions OP1 and a second opening portion OP2.

The plurality of first opening portions OP1 may be areas made by opening the bank 116a, and a part of the third power line PL3 may be exposed. As illustrated in FIGS. 3A, 3B, and 4, the plurality of first opening portions OP1 may be disposed along the plurality of dams DAM. The plurality of first opening portions OP1 may be disposed such that the first portion PL3a surrounds at least a part of the display area AA. For example, the plurality of first opening portions OP1 may be areas made by removing the bank 116a from peripheral portions of the plurality of dams DAM.

With reference to FIGS. 3A, 3B, and 4, the plurality of first opening portions OP1 may be disposed inside the first dam DAM1, between the first dam DAM1 and the second dam DAM2, and outside the second dam DAM2.

In this case, at least a part of the first opening portion OP1 may overlap the first portion PL3a of the third power line PL3. A part of the first opening portion OP1, which is disposed inside the first dam DAM1, and a part of the first opening portion OP1, which is disposed between the first dam DAM1 and the second dam DAM2, may overlap the third power line PL3. Further, the first opening portion OP1, which is disposed outside the second dam DAM2, may not overlap the third power line PL3. However, the present disclosure is not limited thereto.

Meanwhile, with reference to FIGS. 3A and 3B, the connection portion CP is disposed on a portion of the bank 116a that overlaps an end of the first portion PL3a. The connection portion CP is an area between the plurality of first opening portions OP1, i.e., a portion where the first portion PL3a is not exposed by the plurality of first opening portions OP1. Because the connection portion CP is disposed, the first opening portion OP1 may not be disposed at the end of the first portion PL3a. Therefore, the plurality of first opening portions OP1 may not expose the side surface of the first portion PL3a of the third power line PL3. Meanwhile, the connection portion CP may be a portion where the banks 116a included in the first dam DAM1 and the second dam DAM2 extend and are connected to each other.

The second opening portion OP2 may be an area made by opening the bank 116a, and a part of the third power line PL3 may be exposed. The second opening portion OP2 is a portion extending from the first opening portion OP1 and disposed along the side surface of the second portion PL3b of the third power line PL3. The second opening portion OP2 is a portion disposed and extending from the first opening portion OP1 along the side surface of the second portion PL3b. The second opening portion OP2 may extend from the first opening portion OP1 toward the display area AA.

Meanwhile, with reference to FIGS. 3A and 3B, the second opening portion OP2 includes a first sub-opening portion OP2a and a second sub-opening portion OP2b.

The first sub-opening portion OP2a of the second opening portion OP2 may be a portion that overlaps the second portion PL3b and has a line shape. The first sub-opening portion OP2a is disposed to expose the second portion PL3b.

With reference to FIG. 3B, the first sub-opening portion OP2a may be connected to the contact hole CH, which is formed in the bank 116a, to electrically connect the second portion PL3b of the third power line PL3 and the cathode E2. Therefore, the first sub-opening portion OP2a may expand a contact area between the second portion PL3b of the third power line PL3 and the cathode E2 and reduce contact resistance between the third power line PL3 and the cathode E2.

The second sub-opening portion OP2b of the second opening portion OP2 may be a portion having a line shape without overlapping the second portion PL3b. The second sub-opening portion OP2b may be disposed to be spaced apart from the second portion PL3b.

With reference to FIG. 3B, an end of the first sub-opening portion OP2a and an end of the second sub-opening portion OP2b may be connected to each other. That is, the first sub-opening portion OP2a, the second sub-opening portion OP2b, and the first opening portion OP1, which is disposed at the innermost side among the plurality of first opening portions OP1, may be disposed in a closed curve shape that surrounds the display area AA. That is, the banks 116a may be separated and respectively disposed inside and outside the closed curve formed by the first sub-opening portion OP2a, the second sub-opening portion OP2b, and the first opening portion OP1.

Meanwhile, with reference to FIG. 3B, a part of the side surface of the third power line PL3 may be exposed from the bank 116a at the portion where the end of the first sub-opening portion OP2a and the end of the second sub-opening portion OP2b are connected.

The first encapsulation layer 117a, which extends from the display area AA, may be disposed on the bank 116a, a part of the third power line PL3, the first dam DAM1, and the second dam DAM2 in the first non-display area NA1 between the display area AA and the bending area BA.

The first encapsulation layer 117a, which extends from the display area AA, may be disposed on the first dam DAM1 and the second dam DAM2 in the first non-display area NA1 between the display area AA and the bending area BA.

The second encapsulation layer 117b made of an organic insulating material may be positioned only inside the first dam DAM1 in the first non-display area NA1 between the display area AA and the bending area BA.

In addition, in the first non-display area NA1 between the display area AA and the bending area BA, the third encapsulation layer 117c, which extends from the display area AA, may be disposed on the substrate 110, on which the second encapsulation layer 117b is disposed, and cover top surfaces and side surfaces of the first and second encapsulation layers 117a and 117b. The second encapsulation layer 117b may minimize the permeation of outside moisture or oxygen into the first encapsulation layer 117a and the third encapsulation layer 117c.

Meanwhile, with reference to FIGS. 3A to 4, the first encapsulation layer 117a and an end (a) of the third encapsulation layer 117c are disposed outward of the plurality of first opening portions OP1 and spaced apart from the plurality of first opening portions OP1. Therefore, an area in which the first encapsulation layer 117a and the end (a) of the third encapsulation layer 117c are formed, i.e., an area in which an edge of an open portion of a mask for forming the first encapsulation layer 117a and the third encapsulation layer 117c is disposed may be disposed to be spaced apart from a portion where the third power line PL3 is exposed from the plurality of first opening portions OP1.

A method of forming the plurality of inorganic encapsulation layers among the constituent elements of the encapsulation layer in the display device may use a chemical vapor deposition (CVD) method, for example. The chemical vapor deposition method has an advantage of enabling deposition at a low temperature by obtaining high reaction energy from plasma.

However, in the process of forming the plurality of inorganic encapsulation layers by the chemical vapor deposition (CVD) method, an alignment process for precisely aligning a mask used to pattern the plurality of inorganic encapsulation layers may be performed. In this case, the mask is moved to various positions by a motor or the like. During this process, a plurality of electrons may be induced by static electricity at the end of the mask made of metal such as Invar, i.e., the end of the open portion of the mask corresponding to ends of the plurality of inorganic encapsulation layers.

Further, in the case of chemical vapor deposition using plasma, the electrons induced at the end of the open portion of the mask may obtain high reaction energy from the plasma, and as a result, a strong current may be emitted from the end of the mask. Therefore, a burnt defect may occur in constituent elements of the display device adjacent to the open portion of the mask used to form the plurality of inorganic encapsulation layers because of the strong current.

Meanwhile, among the constituent elements of the light-emitting element, the anode may include a plurality of layers including a reflective layer and a plurality of conductive layers. Therefore, a plurality of patterning processes is performed during a process of manufacturing the anode, and as a result, residual films of a plurality of photoresists used in the patterning process may remain on the side surfaces of the anode and the constituent elements disposed on the same layer as the anode. These residual photoresist films may act as vulnerable points when a burnt defect occurs. Therefore, the side surfaces of the anode and the constituent elements disposed on the same layer as the anode may be covered by the bank or the like made of an organic insulating material with excellent insulation properties and non-polarity, thereby protecting the side surfaces of the anode and the constituent elements disposed on the same layer as the anode from the strong current that causes a burnt defect.

Meanwhile, because the bank is made of an organic insulating material with low resistance properties against moisture permeation, the bank, which extends from the non-display area to the display area, may act as a moisture permeation path through which moisture generated in the non-display area propagates into the display area. Therefore, the bank is also disposed to have an open area having a closed curve shape along the plurality of dams that surround the display area, thereby separating the banks disposed in the non-display area and the display area and minimizing propagation of moisture permeation into the display area via the bank.

However, in case that the bank has the open area having the closed curve shape that surrounds the display area, the power line, which is disposed on the same layer as the anode among the power lines configured to transmit the low potential voltage to the cathode from the non-display area, is at least partially and necessarily exposed from the bank. In this case, because a part of the power line exposed from the bank cannot be protected by the bank during the chemical vapor deposition process of forming the plurality of inorganic encapsulation layers, a burnt defect may occur in which the power line exposed from the bank is damaged by the strong current during the chemical vapor deposition process.

Therefore, an area of the open area of the bank disposed in the non-display area, which corresponds to the side surface of the power line disposed on the same layer as the anode, does not open the bank, such that the side surface of the power line may be protected from a burnt defect. However, because a part of the open area of the bank is not open, an additional problem may occur in which moisture permeation propagates from the non-display area to the display area through a portion where the bank is not open.

In the display device 100 according to the embodiment of the present disclosure, the first sub-opening portion OP2a and the second sub-opening portion OP2b of the bank 116a extend along the side surface of the second portion PL3b of the third power line PL3, such that the bank 116a may protect the side surface of the third power line PL3 in the area vulnerable to a burnt defect.

In the display device 100 according to the embodiment of the present disclosure, the bank 116a includes the first sub-opening portion OP2a and the second sub-opening portion OP2b extending from the first opening portion OP1 along the side surface of the second portion PL3b of the third power line PL3. That is, the first sub-opening portion OP2a and the second sub-opening portion OP2b may extend toward the display area AA. The end of the first sub-opening portion OP2a and the end of the second sub-opening portion OP2b may be connected to each other. With the above-mentioned structure, the portion where the third power line PL3 is exposed from the bank 116a may be disposed so as not to be adjacent to the area in which the first encapsulation layer 117a and the end (a) of the third encapsulation layer 117c are formed, i.e., the area vulnerable to a burnt defect. Therefore, the bank 116a may be configured to protect all the side surfaces of the third power line PL3 in an area adjacent to the area in which the first encapsulation layer 117a and the end (a) of the third encapsulation layer 117c are formed. Therefore, in the display device 100 according to the embodiment of the present disclosure, the first sub-opening portion OP2a and the second sub-opening portion OP2b of the bank 116a extend along the side surface of the second portion PL3b of the third power line PL3, such that the bank 116a may be configured to protect the side surface of the third power line PL3 and protect the third power line PL3 in the area vulnerable to a burnt defect, thereby improving reliability of the display device 100.

In the display device 100 according to the embodiment of the present disclosure, the end of the first sub-opening portion OP2a and the end of the second sub-opening portion OP2b of the bank 116a may be connected to each other, thereby minimizing propagation of moisture permeation via the bank 116a.

In the display device 100 according to the embodiment of the present disclosure, the bank 116a includes the first sub-opening portion OP2a and the second sub-opening portion OP2b extending from the first opening portion OP1 along the side surface of the second portion PL3b of the third power line PL3. The end of the first sub-opening portion OP2a and the end of the second sub-opening portion OP2b may be connected to each other. That is, the first sub-opening portion OP2a, the second sub-opening portion OP2b, and the first opening portion OP1, which is disposed at the innermost side among the plurality of first opening portions OP1, may be disposed in a closed curve shape that surrounds the display area AA. Therefore, even though moisture permeation occurs through the bank 116a disposed outside the closed curve formed by the first sub-opening portion OP2a, the second sub-opening portion OP2b, and the first opening portion OP1, the moisture permeation may not propagate to the bank 116a disposed inside the closed curve. Therefore, in the display device 100 according to the embodiment of the present disclosure, the end of the first sub-opening portion OP2a and the end of the second sub-opening portion OP2b of the bank 116a may be connected to each other, thereby minimizing propagation of moisture permeation via the bank 116a and improving display quality of the display device 100.

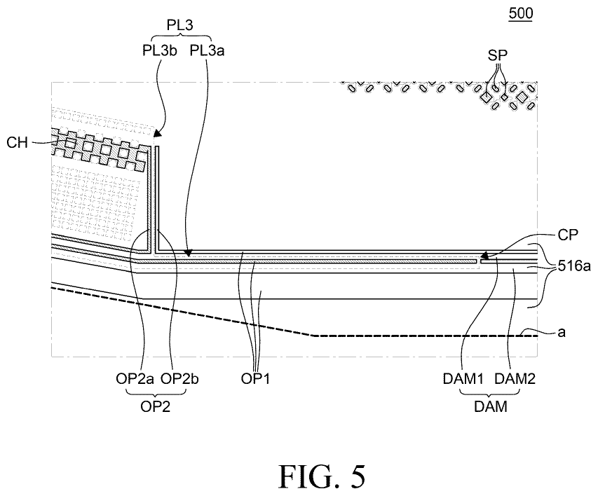

FIG. 5 is an enlarged top plan view of a display device according to another embodiment of the present disclosure. A display device 500 in FIG. 5 differs from the display device 100 in FIGS. 1 to 4 only in terms of the second opening portion OP2. Therefore, repeated descriptions of the substantially identical components will be omitted. The same reference numerals are used for the same components.

With reference to FIG. 5, a bank 516a includes the plurality of first opening portions OP1 and the second opening portion OP2. The second opening portion OP2 includes the first sub-opening portion OP2a and the second sub-opening portion OP2b.

With reference to FIG. 5, the first sub-opening portion OP2a and the second sub-opening portion OP2b may be disposed to be spaced apart from each other. For example, the first sub-opening portion OP2a of the second opening portion OP2 may be a portion that overlaps the second portion PL3b and has a line shape. The first sub-opening portion OP2a is disposed to expose the second portion PL3b. The second sub-opening portion OP2b of the second opening portion OP2 may be a portion having a line shape without overlapping the second portion PL3b. The second sub-opening portion OP2b may be disposed to be spaced apart from the second portion PL3b. Therefore, because the first sub-opening portion OP2a and the second sub-opening portion OP2b are disposed to be spaced apart from each other, the plurality of first opening portions OP1 and the second opening portion OP2 of the bank 516a may be configured not to expose the side surface of the third power line PL3 disposed below the bank 516a.

In the display device 500 according to another embodiment of the present disclosure, the first sub-opening portion OP2a and the second sub-opening portion OP2b of the bank 516a extend along the side surface of the second portion PL3b of the third power line PL3 and are disposed to be spaced apart from each other, such that the bank 516a may protect the side surface of the third power line PL3 in the area vulnerable to a burnt defect.

In the display device 500 according to another embodiment of the present disclosure, the bank 516a includes the first sub-opening portion OP2a and the second sub-opening portion OP2b extending from the first opening portion OP1 along the side surface of the second portion PL3b of the third power line PL3. That is, the first sub-opening portion OP2a and the second sub-opening portion OP2b may extend toward the display area AA. The first sub-opening portion OP2a and the second sub-opening portion OP2b may be disposed to be spaced apart from each other. With the above-mentioned structure, the third power line PL3 may be configured such that the side surface thereof is not exposed in the area in which the first encapsulation layer 117a and the end (a) of the third encapsulation layer 117c are formed, i.e., the area vulnerable to a burnt defect. That is, the plurality of first opening portions OP1 and the second opening portion OP2 of the bank 516a may be configured not to expose the side surface of the third power line PL3 disposed below the bank 516a. Therefore, the bank 516a may be configured to protect all the side surfaces of the third power line PL3 in an area adjacent to the area in which the first encapsulation layer 117a and the end (a) of the third encapsulation layer 117c are formed. Therefore, in the display device 500 according to another embodiment of the present disclosure, the first sub-opening portion OP2a and the second sub-opening portion OP2b of the bank 516a extend along the side surface of the second portion PL3b of the third power line PL3 and are disposed to be spaced apart from each other, such that the bank 516a may protect the side surface of the third power line PL3 in the area vulnerable to a burnt defect, thereby improving reliability of the display device 500.

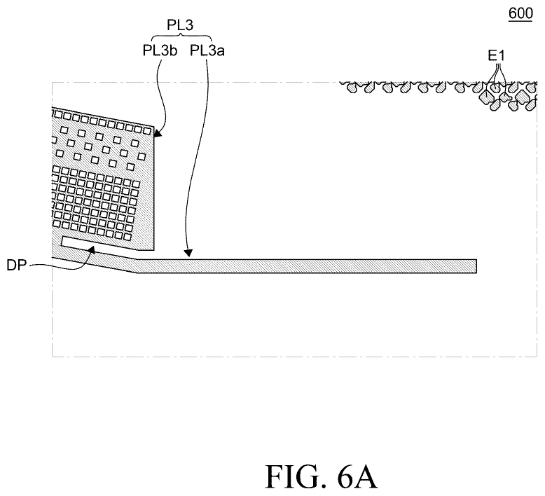

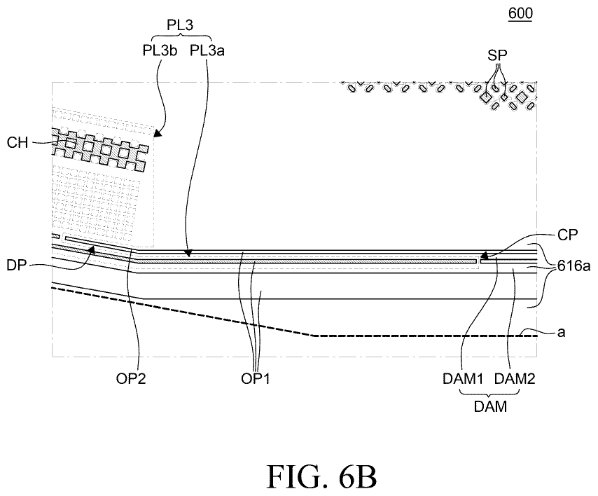

FIGS. 6A and 6B are enlarged top plan views of a display device according to still another embodiment of the present disclosure. A display device 600 in FIGS. 6A and 6B differs from the display device 100 in FIGS. 1 to 4 only in terms of the second opening portion OP2. Therefore, repeated descriptions of the substantially identical components will be omitted. The same reference numerals are used for the same components.

With reference to FIGS. 6A and 6B, the third power line PL3 includes a concave portion DP. The third power line PL3 includes the concave portion DP concavely extending inward from the side surface of the second portion PL3b adjacent to the first portion PL3a. As illustrated in FIG. 6B, the concave portion DP may be a portion may be formed by removing a part of the third power line PL3.

With reference to FIGS. 6A and 6B, the second opening portion OP2 of a bank 616a is disposed in the concave portion DP on the side surface of the second portion PL3b. In this case, the second opening portion OP2 is disposed to be spaced apart from the concave portion DP. Therefore, the second opening portion OP2 may be configured not to expose the side surface of the third power line PL3.

Meanwhile, because the second opening portion OP2 is disposed in the concave portion DP of the second portion PL3b, a length of a path, through which moisture permeation propagates from the connection portion CP toward the display area AA may increase by a length of the second opening portion OP2 disposed in the concave portion DP in the bank 616a. Therefore, the second opening portion OP2 may be disposed in the concave portion DP of the second portion PL3b, thereby minimizing propagation of moisture permeation to the display area AA through the connection portion CP in the bank 616a.

In the display device 600 according to still another embodiment of the present disclosure, the third power line PL3 includes the concave portion DP, and the second opening portion OP2 of the bank 616a is disposed in the concave portion DP and spaced apart from the concave portion DP, such that the bank 616a may protect the side surface of the third power line PL3 in the area vulnerable to a burnt defect.

In the display device 600 according to still another embodiment of the present disclosure, the third power line PL3 includes the concave portion DP concavely extending inward from the side surface of the second portion PL3b adjacent to the first portion PL3a. Further, the second opening portion OP2 of the bank 616a disposed on the side surface of the second portion PL3b, disposed in the concave portion DP, and spaced apart from the concave portion DP. Therefore, the second opening portion OP2 may be configured not to expose the side surface of the third power line PL3. With the above-mentioned structure, the third power line PL3 may be configured such that the side surface thereof is not exposed in the area in which the first encapsulation layer 117a and the end (a) of the third encapsulation layer 117c are formed, i.e., the area vulnerable to a burnt defect. That is, the plurality of first opening portions OP1 and the second opening portion OP2 of the bank 616a may be configured not to expose the side surface of the third power line PL3 disposed below the bank 616a. Therefore, the bank 616a may be configured to protect all the side surfaces of the third power line PL3 in the area adjacent to the area in which the first encapsulation layer 117a and the end (a) of the third encapsulation layer 117c are formed. In the display device 600 according to still another embodiment of the present disclosure, the third power line PL3 includes the concave portion DP, and the second opening portion OP2 of the bank 616a is disposed in the concave portion DP and spaced apart from the concave portion DP, such that the bank 616a may protect the side surface of the third power line PL3 in the area vulnerable to a burnt defect, thereby improving reliability of the display device 600.

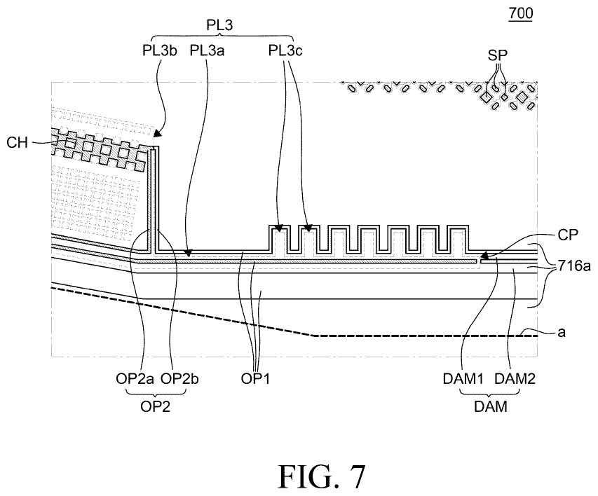

FIG. 7 is an enlarged top plan view of a display device according to yet another embodiment of the present disclosure. A display device 700 in FIG. 7 differs from the display device 100 in FIGS. 1 to 4 only in that the third power line PL3 further includes a third portion PL3c. Therefore, repeated descriptions of the substantially identical components will be omitted. The same reference numerals are used for the same components.

With reference to FIG. 7, the third power line PL3 further includes a plurality of third portions PL3c. The plurality of third portions PL3c are disposed to be spaced apart from the second portion PL3b. The plurality of third portions PL3c extend in a first direction toward the display area AA. All the plurality of third portions PL3c may extend straight in the same first direction.

With reference to FIG. 7, the first opening portion OP1, which is disposed at the innermost side among the plurality of first opening portions OP1 of a bank 716a, is disposed to be spaced apart from the plurality of third portions PL3c and surround the plurality of third portions PL3c. Therefore, the plurality of third portions PL3c may not overlap the first opening portion OP1 disposed at the innermost side. That is, the plurality of third portions PL3c may not be exposed from the bank 716a.

In the display device 700 according to yet another embodiment of the present disclosure, the third power line PL3 further includes the plurality of third portions PL3c, and the first opening portion OP1 is disposed to be spaced apart from the plurality of third portions PL3c and surround the plurality of third portions PL3c, thereby further minimizing propagation of moisture permeation via the bank 716a.

In the display device 700 according to yet another embodiment of the present disclosure, the third power line PL3 further includes the plurality of third portions PL3c. The plurality of third portions PL3c extend in the first direction toward the display area AA. Further, the first opening portion OP1, which is disposed at the innermost side among the plurality of first opening portions OP1 of the bank 716a, is disposed to be spaced apart from the plurality of third portions PL3c and surround the plurality of third portions PL3c. Therefore, the plurality of third portions PL3c may not be exposed from the bank 716a. With the above-mentioned structure, a length of a path through which moisture permeation propagates from the connection portion CP toward the display area AA may increase by a length of a rim of the plurality of third portions PL3c. Therefore, the propagation of moisture permeation to the display area AA through the connection portion CP in the bank 716a may be minimized. Therefore, in the display device 700 according to yet another embodiment of the present disclosure, the third power line PL3 further includes the plurality of third portions PL3c, and the first opening portion OP1 is disposed to be spaced apart from the plurality of third portions PL3c and surround the plurality of third portions PL3c, thereby further minimizing propagation of moisture permeation via the bank 716a and further improving display quality of the display device 700.

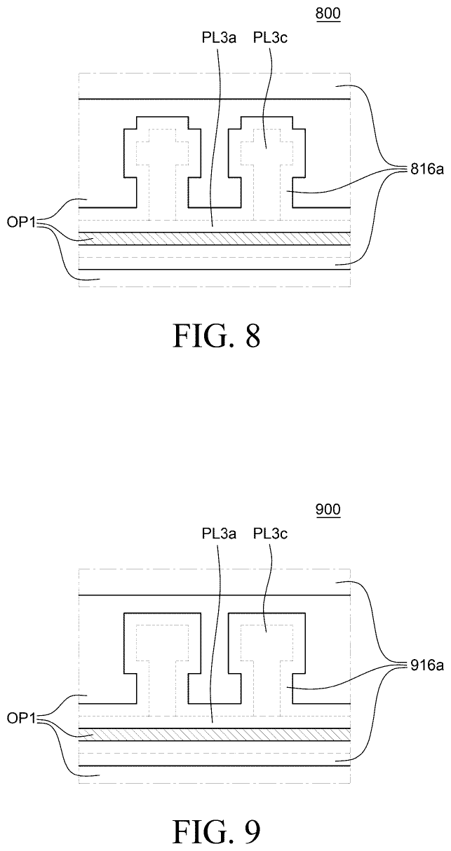

FIG. 8 is an enlarged top plan view of a display device according to still yet another embodiment of the present disclosure. A display device 800 in FIG. 8 differs from the display device 700 in FIG. 7 only in terms of the third opening portion PL3c. Therefore, repeated descriptions of the substantially identical components will be omitted. The same reference numerals are used for the same components.

With reference to FIG. 8, the plurality of third portions PL3c of the third power line PL3 extends in the first direction and a second direction intersecting the first direction. For example, a shape defined by the plurality of third portions PL3c may be a ‘+’ shape. However, the present disclosure is not limited thereto.

With reference to FIG. 8, the first opening portion OP1, which is disposed at the innermost side among the plurality of first opening portions OP1 of a bank 816a, is disposed to be spaced apart from the plurality of third portions PL3c and surround the plurality of third portions PL3c. Therefore, the plurality of third portions PL3c may not overlap the first opening portion OP1 disposed at the innermost side. That is, the plurality of third portions PL3c may not be exposed from the bank 816a.

In the display device 800 according to still yet another embodiment of the present disclosure, the plurality of third portions PL3c extends in the first direction and the second direction intersecting the first direction, and the first opening portion OP1 is disposed to be spaced apart from the plurality of third portions PL3c and surround the plurality of third portions PL3c, thereby further minimizing propagation of moisture permeation via the bank 816a.

In the display device 800 according to still yet another embodiment of the present disclosure, the third power line PL3 further includes the plurality of third portions PL3c. The plurality of third portions PL3c extend in the first direction and the second direction intersecting the first direction. The shape defined by the plurality of third portions PL3c may be a ‘+’ shape. Further, the first opening portion OP1, which is disposed at the innermost side among the plurality of first opening portions OP1 of the bank 816a, is disposed to be spaced apart from the plurality of third portions PL3c and surround the plurality of third portions PL3c. Therefore, the plurality of third portions PL3c may not be exposed from the bank 816a. With the above-mentioned structure, a length of a path through which moisture permeation propagates from the connection portion CP toward the display area AA may increase by a length of a rim of the plurality of third portions PL3c. Therefore, the propagation of moisture permeation to the display area AA through the connection portion CP in the bank 816a may be minimized. Therefore, in the display device 800 according to still yet another embodiment of the present disclosure, the plurality of third portions PL3c extends in the first direction and the second direction intersecting the first direction, and the first opening portion OP1 is disposed to be spaced apart from the plurality of third portions PL3c and surround the plurality of third portions PL3c, thereby further minimizing propagation of moisture permeation via the bank 816a and further improving display quality of the display device 800.

FIG. 9 is an enlarged top plan view of a display device according to a further embodiment of the present disclosure. A display device 900 in FIG. 9 differs from the display device 700 in FIG. 7 only in terms of the third opening portion PL3c. Therefore, repeated descriptions of the substantially identical components will be omitted. The same reference numerals are used for the same components.

With reference to FIG. 9, the plurality of third portions PL3c of the third power line PL3 extend in the first direction and the second direction intersecting the first direction. For example, a shape defined by the plurality of third portions PL3c may be a ‘T’ shape. However, the present disclosure is not limited thereto.

With reference to FIG. 9, the first opening portion OP1, which is disposed at the innermost side among the plurality of first opening portions OP1 of a bank 916a, is disposed to be spaced apart from the plurality of third portions PL3c and surround the plurality of third portions PL3c. Therefore, the plurality of third portions PL3c may not overlap the first opening portion OP1 disposed at the innermost side. That is, the plurality of third portions PL3c may not be exposed from the bank 916a.

In the display device 900 according to the further embodiment of the present disclosure, the plurality of third portions PL3c extends in the first direction and the second direction intersecting the first direction, and the first opening portion OP1 is disposed to be spaced apart from the plurality of third portions PL3c and surround the plurality of third portions PL3c, thereby further minimizing propagation of moisture permeation via the bank 916a.

In the display device 900 according to the further embodiment of the present disclosure, the third power line PL3 further includes the plurality of third portions PL3c. The plurality of third portions PL3c extend in the first direction and the second direction intersecting the first direction. For example, the shape defined by the plurality of third portions PL3c may be a ‘T’ shape. Further, the first opening portion OP1, which is disposed at the innermost side among the plurality of first opening portions OP1 of the bank 916a, is disposed to be spaced apart from the plurality of third portions PL3c and surround the plurality of third portions PL3c. Therefore, the plurality of third portions PL3c may not be exposed from the bank 916a. With the above-mentioned structure, a length of a path through which moisture permeation propagates from the connection portion CP toward the display area AA may increase by a length of a rim of the plurality of third portions PL3c. Therefore, the propagation of moisture permeation to the display area AA through the connection portion CP in the bank 916a may be minimized. Therefore, in the display device 900 according to the further embodiment of the present disclosure, the plurality of third portions PL3c extends in the first direction and the second direction intersecting the first direction, and the first opening portion OP1 is disposed to be spaced apart from the plurality of third portions PL3c and surround the plurality of third portions PL3c, thereby further minimizing propagation of moisture permeation via the bank 916a and further improving display quality of the display device 900.

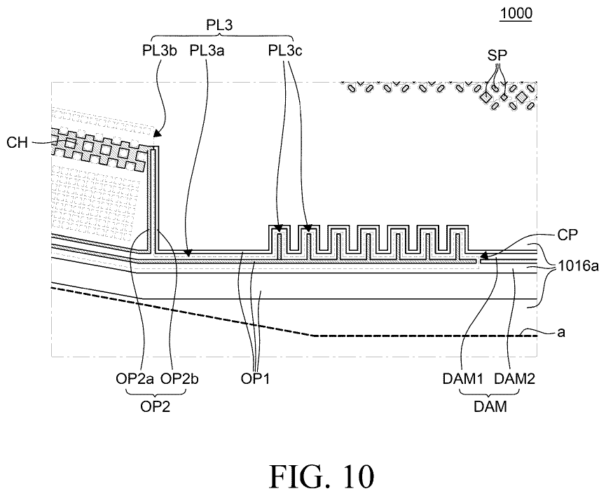

FIG. 10 is an enlarged top plan view of a display device according to another further embodiment of the present disclosure. A display device 1000 in FIG. 10 differs from the display device 700 in FIG. 7 only in terms of the first opening portion OP1. Therefore, repeated descriptions of the substantially identical components will be omitted. The same reference numerals are used for the same components.

With reference to FIG. 10, the third power line PL3 further includes the plurality of third portions PL3c. The plurality of third portions PL3c are disposed to be spaced apart from the second portion PL3b. The plurality of third portions PL3c extend in the first direction toward the display area AA. All the plurality of third portions PL3c may extend straight in the same first direction.

With reference to FIG. 10, the first opening portion OP1, which is disposed at the innermost side among the plurality of first opening portions OP1 of a bank 1016a, is disposed to be spaced apart from the plurality of third portions PL3c and surround the plurality of third portions PL3c. Further, the first opening portion OP1, which overlaps the first portion PL3a among the plurality of first opening portions OP1, is disposed and extends to overlap the third portion PL3c. Therefore, the bank 1016a disposed between the plurality of first opening portions OP1 may have a wavy line shape, for example.

In the display device 1000 according to another further embodiment of the present disclosure, the third power line PL3 further includes the plurality of third portions PL3c, and the first opening portion OP1 is disposed to have a wavy line shape, thereby further minimizing propagation of moisture permeation via the bank 1016a.

In the display device 1000 according to another further embodiment of the present disclosure, the third power line PL3 further includes the plurality of third portions PL3c. The plurality of third portions PL3c extend in the first direction toward the display area AA. Further, the first opening portion OP1, which is disposed at the innermost side among the plurality of first opening portions OP1 of the bank 716a, is disposed to be spaced apart from the plurality of third portions PL3c and surround the plurality of third portions PL3c. In this case, the first opening portion OP1, which overlaps the first portion PL3a among the plurality of first opening portions OP1, is disposed and extends to overlap the third portion PL3c. Therefore, the bank 1016a disposed between the plurality of first opening portions OP1 may have a wavy line shape, for example. With the above-mentioned structure, a length of a path through which moisture permeation propagates from the connection portion CP toward the display area AA may increase by a length of the wavy line shape. Therefore, the propagation of moisture permeation to the display area AA through the connection portion CP in the bank 1016a may be minimized. Therefore, in the display device 1000 according to another further embodiment of the present disclosure, the third power line PL3 further includes the plurality of third portions PL3c, and the first opening portion OP1 is disposed to have a wavy line shape, thereby further minimizing propagation of moisture permeation via the bank 1016a and further improving display quality of the display device 1000.

The example embodiments of the present disclosure can also be described as follows:

According to an aspect of the present disclosure, a display device may include a substrate; a display area in which a plurality of subpixels is disposed, and a non-display area outside the display area; a plurality of light-emitting elements respectively disposed in the plurality of subpixels on the substrate, each light-emitting element comprising an anode, a light-emitting layer, and a cathode; a bank disposed in the display area and the non-display area and covering an end of the anode; a dam disposed in the non-display area on the substrate and configured to surround the display area; and a power line configured to partially overlap the dam in the non-display area, disposed on a same layer as the anode, and made of a same material as the anode. The power line may comprise a first portion that is a portion overlapping the dam; and a second portion that is a portion extending from the first portion toward the display area. The bank may comprise a plurality of first opening portions disposed along the dam; and a second opening portion extending from a first opening portion and disposed along a side surface of the second portion. The plurality of first opening portions may comprise the first opening portion.

The bank may further comprise a connection portion that is a portion overlapping an end of the first portion between the plurality of first opening portions without exposing the end of the first portion.

The second opening portion may comprise a first sub-opening portion overlapping the second portion and having a line shape; and a second sub-opening portion spaced apart from the second portion and having a line shape.

The cathode may be electrically connected to the second portion of the power line through a contact hole disposed in the bank.

The first sub-opening portion may be connected to the contact hole.

An end of the first sub-opening portion and an end of the second sub-opening portion may be connected to each other.

The first sub-opening portion and the second sub-opening portion may be spaced apart from each other.

The power line may comprise a concave portion concavely extending inward from the side surface of the second portion adjacent to the first portion.

The second opening portion may be disposed in the concave portion.

The second opening portion may be spaced apart from the concave portion of the power line.

The power line may further comprise a plurality of third portions spaced apart from the second portion and extending in a first direction toward the display area.

A first opening portion, which is disposed at an innermost side among the plurality of first opening portions, may be spaced apart from the third portion and surround the third portion.

All of the plurality of third portions may extend straight in the same first direction.

The plurality of third portions may extend in the first direction and a second direction intersecting the first direction.

A shape defined by the plurality of third portions may be a ‘T’ shape or a ‘+’ shape.

The third portion may not overlap the first opening portion.

A first opening portion, which overlaps the first portion among the plurality of first opening portions, may overlap the third portion.

The display device may further comprise an encapsulation layer disposed above the plurality of light-emitting elements, disposed in a part of the display area and a part of the non-display area, and comprising a plurality of inorganic layers and organic layers.

Ends of the plurality of inorganic layers of the encapsulation layer may be disposed outward of the plurality of first opening portions and may be spaced apart from the plurality of first opening portions.

According to another aspect of the present disclosure, a display device may comprise a substrate; a display area and a non-display area; a plurality of light-emitting elements disposed in the display area on the substrate, each light-emitting element comprising an anode, a light-emitting layer, and a cathode; a bank disposed on the anode and covering an end of the anode; and a power line disposed in the non-display area, disposed on a same layer as the anode, made of a same material as the anode, and electrically connected to the cathode. The power line may comprise a first portion disposed in the non-display area and disposed to surround at least a part of the display area; and a second portion that is a portion protruding from the first portion toward the display area. The bank may comprise a plurality of first opening portions disposed to surround at least a part of the display area and configured to at least partially overlap the first portion; and a second opening portion disposed to extend from a first opening portion along a side surface of the second portion. The plurality of first opening portions may comprise the first opening portion.

The bank may further comprise a connection portion that is a portion overlapping an end of the first portion without exposing the end of the first portion.

The second opening portion may comprise a first sub-opening portion overlapping the second portion and having a line shape; and a second sub-opening portion spaced apart from the second portion and having a line shape.

The display device may further comprise an encapsulation layer disposed above the plurality of light-emitting elements, disposed in a part of the display area and a part of the non-display area, and comprising a plurality of inorganic layers and organic layers.

Ends of the plurality of inorganic layers of the encapsulation layer may be disposed outward of the plurality of first opening portions and may be spaced apart from the plurality of first opening portions.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate;
a display area in which a plurality of subpixels is disposed, and a non-display area outside the display area;
a plurality of light-emitting elements respectively disposed in the plurality of subpixels on the substrate, each light-emitting element comprising an anode, a light-emitting layer, and a cathode;
a bank disposed in the display area and the non-display area and covering an end of the anode;
a dam disposed in the non-display area on the substrate and configured to surround the display area; and
a power line configured to partially overlap the dam in the non-display area, disposed on a same layer as the anode, and made of a same material as the anode,
wherein the power line comprises:
a first portion that is a portion overlapping the dam; and
a second portion that is a portion extending from the first portion toward the display area,
wherein the bank comprises:
a plurality of first opening portions disposed along the dam; and
a second opening portion extending from a first opening portion and disposed along a side surface of the second portion, and
wherein the plurality of first opening portions comprises the first opening portion.

2. The display device of claim 1, wherein the bank further comprises a connection portion that is a portion overlapping an end of the first portion between the plurality of first opening portions without exposing the end of the first portion.

3. The display device of claim 2, wherein the second opening portion comprises:
a first sub-opening portion overlapping the second portion and having a line shape; and
a second sub-opening portion spaced apart from the second portion and having a line shape.

4. The display device of claim 3, wherein the cathode is electrically connected to the second portion of the power line through a contact hole disposed in the bank, and
the first sub-opening portion is connected to the contact hole.

5. The display device of claim 3, wherein an end of the first sub-opening portion and an end of the second sub-opening portion are connected to each other.

6. The display device of claim 3, wherein the first sub-opening portion and the second sub-opening portion are spaced apart from each other.

7. The display device of claim 1, wherein the power line comprises a concave portion concavely extending inward from the side surface of the second portion adjacent to the first portion, and
wherein the second opening portion is disposed in the concave portion.

8. The display device of claim 7, wherein the second opening portion is spaced apart from the concave portion of the power line.

9. The display device of claim 1, wherein the power line further comprises a plurality of third portions spaced apart from the second portion and extending in a first direction toward the display area, and
wherein a first opening portion, which is disposed at an innermost side among the plurality of first opening portions, is spaced apart from a third portion and surrounds the third portion, and
wherein the plurality of third portions comprises the third portion.

10. The display device of claim 9, wherein all of the plurality of third portions extends straight in the same first direction.

11. The display device of claim 9, wherein the plurality of third portions extends in the first direction and a second direction intersecting the first direction.

12. The display device of claim 11, wherein a shape defined by the plurality of third portions is a ‘T’ shape or a ‘+’ shape.

13. The display device of claim 9, wherein the third portion does not overlap the first opening portion.

14. The display device of claim 9, wherein a first opening portion, which overlaps the first portion among the plurality of first opening portions, overlaps the third portion.

15. The display device of claim 1, further comprising:
an encapsulation layer disposed above the plurality of light-emitting elements, disposed in a part of the display area and a part of the non-display area, and comprising a plurality of inorganic layers and organic layers,
wherein ends of the plurality of inorganic layers of the encapsulation layer are disposed outward of the plurality of first opening portions and are spaced apart from the plurality of first opening portions.

16. A display device, comprising:
a substrate;
a display area and a non-display area;
a plurality of light-emitting elements disposed in the display area on the substrate, each light-emitting element comprising an anode, a light-emitting layer, and a cathode;
a bank disposed on the anode and covering an end of the anode; and
a power line disposed in the non-display area, disposed on a same layer as the anode, made of a same material as the anode, and electrically connected to the cathode,
wherein the power line comprises:
a first portion disposed in the non-display area and disposed to surround at least a part of the display area; and
a second portion that is a portion protruding from the first portion toward the display area,
wherein the bank comprises:
a plurality of first opening portions disposed to surround at least a part of the display area and configured to at least partially overlap the first portion; and
a second opening portion disposed to extend from a first opening portion along a side surface of the second portion, and
wherein the plurality of first opening portions comprises the first opening portion.

17. The display device of claim 16, wherein the bank further comprises a connection portion that is a portion overlapping an end of the first portion without exposing the end of the first portion.

18. The display device of claim 16, wherein the second opening portion comprises:
a first sub-opening portion overlapping the second portion and having a line shape; and
a second sub-opening portion spaced apart from the second portion and having a line shape.

19. The display device of claim 16, further comprising:
an encapsulation layer disposed above the plurality of light-emitting elements, disposed in a part of the display area and a part of the non-display area, and comprising a plurality of inorganic layers and organic layers,
wherein ends of the plurality of inorganic layers of the encapsulation layer are disposed outward of the plurality of first opening portions and are spaced apart from the plurality of first opening portions.
